(19) United States
(12) Patent Application Publication
(10) Pub. No.: US 2008/0143357 A1
(43) Pub. Date: Jun. 19, 2008

(54) HIGH POWER COBRA INTERPOSER WTIH INTEGRATED GUARD PLATE

(75) Inventors: Paul M. Gaschke, Wappingers Falls, NY (US); Karlheinz G. Schoenfeld, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/610,139

(22) Filed: Dec. 13, 2006

(51) Int. Cl. G01R 1/067; G01R 31/26

(52) U.S. Cl. 324/754

(57) ABSTRACT

A high power Cobra interposer with an integrated guard plate, which is utilized for the testing of electrical products. The guard plate and the upper die of the interposer assembly are integrated into a single unit, thereby eliminating a portion of the structure. The Cobra structure utilizes a novel hole configuration in the upper die portion of the interposer structure, whereby only a small portion of the Cobra tip protrudes, rendering it less susceptible to being damaged in comparison with current designs.

### BACKGROUND OF THE INVENTION

1. Field of the Invention

The present invention relates to the provision of a high power Cobra interposer with an integrated guard plate, which is utilized for the testing of electrical products.

In the electronics technology, numerous semiconductor products are tested at the module level in a so-called “burn-in” test whereby a significant proportion thereof are contacted by means of a specialized socket which utilizes so-called Cobra or snake-like wire contacts. These Cobra contacts are housed in an assembly, which is referred to as an interposer and protrude from the top thereof, so as to align with holes that are formed in a movable guard plate. Upon depression of the guard plate, the electrical contacts at the protruding ends of the Cobra pass through the holes in the movable guard plate and are pressed against the product module mounting the semiconductor product so as to produce a temporary electrical connection providing information as to the integrity of the semiconductor products.

2. Discussion of the Prior Art

Presently, Cobra interposer and guard plate designs, which are utilized in the burn-in testing of semiconductor products, are subject to various problems, which at times may lead to incorrect readings and resultingly potential failures of the testing equipment.

In essence, among the drawbacks, which are currently encountered may be that the guard plate, which generally constituted of a coated metal part, occasionally electrically shorts to the module. Furthermore, the interposer dies, which mount the Cobra contacts, are normally produced from a ceramic base material and have a tendency to break during repeated use, whereas in addition thereto, the Cobra contacts are easily bent during use and sometimes tend to stick in the holes, which are formed in the guard plate. Moreover, the electrical current and carrying capacity of the Cobra contacts may not be sufficient for newer up-to-date semiconductor products, which frequently require higher current levels, whereby the foregoing problems may result in increased maintenance costs and in reduced hardware utilization.

The above problems are currently being addressed in the technology by either providing a more robust coating of the metallic guard plate, which may provide some significant alleviation of the problems, however inasmuch as the base metal structure thereof is still employed, there may also be a potential residual problem of electrical short-circuiting.

A new Cobra hole-drilling design may be utilized, which may render the dies more robust, but the material may always still be brittle, inasmuch as it is based on a ceramic-based structure. Furthermore, the unacceptable bending of the pins of the Cobra contacts can only be addressed through a training of skilled operators, and may represent a problem in current designs, whereas the sticking contacts of the Cobras may also present a cleanliness issue and must be constantly monitored. As an alternative, so-called pogo contacts have been utilized for the highest-current or power semiconductor products but are extremely expensive, and a vendor socket solution has been qualified, but the current capacity thereof is only half of that of the pogo.

Concerning the foregoing, although numerous publications are in evidence which address the probing of electrical equipment through, for example, burn-in testing, these have not fully solved the difficulties, as described hereinabove. In particular, Satou, et al., U.S. Patent Publication No. 2004/0257098 A1 discloses a probe card, which provides for the ready assembly and testing of various electrical products.

Similarly, Okubo, et al., U.S. Pat. No. 6,300,783 B1 describes equipment and methods for testing electrical semiconductor products. Also similarly, Vinh, U.S. Pat. No. 5,952,843 discloses a plurality of wire type contacts, which pass through the interposer plate and guard plate in order to be able to have the protruding ends provide electrical connections of a temporary nature with semiconductor products.

The foregoing is also applicable to Nam, U.S. Pat. No. 5,850,148, which discloses a vertical probe card apparatus having needles for contacting semiconductor products; and finally, the publication by Kulicke & Soffa, entitled “Cobra FP Probe Card for Multi-Dut Logic & Memory Applications” provides for a Cobra probe card which, however, requires the utilization of interposer structures that are subject to the disadvantages or drawbacks described hereinabove.

### SUMMARY OF THE INVENTION

Accordingly, in order to obviate or ameliorate the drawbacks and disadvantages encountered in the prior art with regard to the burn-in testing of semiconductor products, the present invention relates to a novel redesign configuration in the testing of equipment, wherein the guard plate and the upper die of the interposer assembly are integrated into a single unit thereby eliminating a portion of the structure which heretofore has exhibited a tendency to generate the difficulties encountered in the prior art aspects of semiconductor testing utilizing the Cobra contact design, wherein the present invention relates to the utilization of a non-ceramic die material and a new and novel Cobra contact.

In essence, the present invention is directed to a Cobra structure utilizing a novel hole configuration in the upper die portion of the interposer structure, whereby only a small portion of the Cobra tip protrudes, rendering it less susceptible to being damaged in comparison with current designs. Moreover, the present structure eliminates the sticking features and is plug compatible with existing design structure making qualification implementation a simple task to one of skill in this particular testing technology.

### BRIEF DESCRIPTION OF THE DRAWINGS

Reference may now be made to the following detailed description of a preferred embodiment of the invention, taken in conjunction with the accompanying drawings; in which:

FIG. 1 illustrates a perspective presentation of a part of a Cobra socket structure with a corner of a guard plate cut away pursuant to the prior art;

FIG. 2 illustrates a perspective plan representation of a structure for a contact housing and a die pursuant to the present invention; and

FIGS. 3A through 3C illustrate the operation of a single Cobra contact in respectively open, initial contact with a module and closed positions.

### DETAILED DESCRIPTION OF THE INVENTION

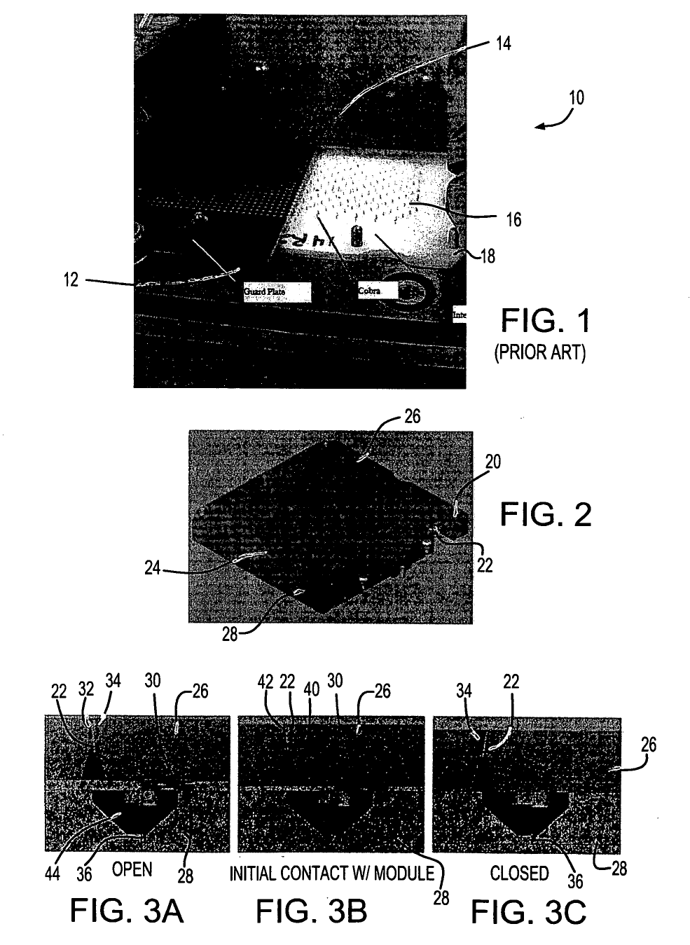

Reverting to the drawings in specific detail, FIG. 1 perspectively illustrates a portion of a structure of a prior art socket arrangement 10 with a corner of a guard plate 12 cut away, wherein the guard plate is essentially constituted of a coated metal having a plurality of apertures or holes 14 through which the tips of a Cobra contact 16, which is mounted on an interposer die or plate 18, may pass through upon depression of the guard plate 12. In particular, the Cobra contacts 16 are mounted on the interposer plate 18, which is normally of a ceramic or plastic material. In particular, as indicated previously, the guard plate 12, which is a coated metal component, sometimes electronically shorts to the testing module (not shown), thereby providing potentially erroneous electrical output data.

The interposer die 18, which is formed of a plate comprised of a ceramic based material and which mounts the Cobra contacts 16 adapted to project upwardly therefrom into and through the holes 14 of the guard plate 12, may, upon occasion, break by being of a relatively fragile nature, and moreover, the Cobra contacts are easily bent and possibly stick in the holes of the guard plate. Moreover, as indicated, the Cobra contact electrical current capacity may not be sufficient for new and contemplated future semiconductor products which require higher electrical power.

Reverting to the present invention, there is eliminated the intermediate interposer plate and in that there is shown in FIG. 2, for example, only a single cut away die hole 20 and contact 22 in a cut-away portion of the interposer 24. An upper die 26 is shown in this extended position and the gap between it and a lower die 28 can be clearly ascertained (FIGS. 3A-3C). The dies 26, 28 are interconnected by means of springs 30, which can force the upper die into its extended position, and a pair of shoulder screw stops can also be provided herein.

As indicated, in the open or extended view of the dies 26, 28, as shown in FIG. 3A, the Cobra contact 22 is protected within the through hole 32 of the upper die, the latter of which may have a funnel shape configuration and which will prevent sticking of the cobra contact in the hole or aperture formed therein. Moreover, only a short distance of the Cobra tip 34, for example, 0.010″, protrudes from the upper die 26, rendering it much less susceptible to being damaged in comparison with the extensive projection of the Cobra contact 16 from the interposer plate through the guard plate, as shown in the prior art pursuant to FIG. 1 of the drawings. As indicated in FIG. 3B of the drawings, in the initial contact with the module, the upper die 26 is partly deflected downwardly to a point where the Cobra tip 34 would be just contacting the module (not shown) which mounts the semiconductor product, whereas in the fully closed view of FIG. 3C, the upper die 26 is fully deflected and the Cobra 22 is in full compression against the module (not shown). Concerning the foregoing, the various structures of the Cobra and its functioning provides an important feature, not at all disclosed in the prior art, as follows:

One very key feature to making this concept work is the locking of the swaged end 36 of the Cobra 22 into the lower die 28. Without this feature, when the upper die 26 is returned to the extended position (FIG. 3A), many of the Cobra contacts would be lifted upwardly off of the PCB. This would cause unstable contacting with the PCB and would allow the Cobra to protrude further then 0.010″ from the upper die 26 making it more vulnerable to damage. This feature is accomplished through a unique hole profile through which the swaged end 36 of the Cobra 22 is pressed. When the swage passes through the press fit zone, it is free to operate as usual. This feature also drives a new loading technique that requires the contacts be pressed into the lower die first, then the upper die is slid over the Cobra shanks.

The key feature that enables the guard plate to properly function and eliminates sticking pins, is the design of Cobra shank support hole 40 in the upper die 26. The narrow portion 42 of the hole 40 has an unconventional minimal length giving the Cobra 22 an extra degree of freedom designed to eliminate sticking pins. Beyond this hole is a larger hole 44 designed to give the Cobra 22 limited freedom to “wipe” and at the same time protect/support the shank.

The Cobra contact itself can be re-engineered to handle more current. A larger diameter wire made from a lower resistance material with modifications to the formed geometry is necessary to achieve a 4-amp cluster specification.

From the foregoing, it becomes readily apparent that the present structure in the provision of the Cobra interposer for testing semiconductor products provides important distinctions over the prior art and advantages in the function and reliability thereof.

Although the foregoing concept is adapted for the contacting of land grid arrays (LGAs) products, a variation of the concept may enable ball grid arrays (BGAs) to be contacted. Moreover, although the concept is designed for burn-in testing of semiconductor products, it may also be applied potentially in test socket areas of the technology.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but to fall within the spirit and scope of the appended claims.

1. An arrangement for the testing of electrical products at a wafer or semiconductor chip module level, said arrangement comprising:
a first die plate member having a plurality of apertures formed therein;
a second die plate member arranged in a closely spaced surface relationship with said first die plate member having a plurality of through-extending apertures formed therein in substantial alignment with the apertures in said first die plate member;
resilient spring elements interconnecting said first and second die plate members to facilitated said second die plate member being biased into surface contact with said first die plate member responsive to pressure exerted by a wafer or chip module which is being tested against an opposite surface of said second die plate member;
a flexible wire extending through, respectively, each of the apertures of said first and second die plate members, each said flexible wire having one end anchored in said first die plate member and an opposite end forming an electrical contact with said module during testing of the electrical products;
said second die plate member being normally maintained in a spaced relationship with said first die plate member during which the tip of each of said flexible wire forming the electrical contact is recessed with the therewith associated aperture in said second die plate member;
the tip of each said flexible wire forming the electrical contact projecting from the aperture associated therewith into contact with the module upon said second die plate member being pressed by said module opposite the biasing force of resilient spring elements tending to separate said first and second die plate members; and
each aperture in said second die plate member having a V-shaped cross-section over a portion of the thickness of said die plate member, which widens towards the first die plate member, and at the apex of said V-shaped cross-section, said aperture comprising a transition zone into a wider cylindrical cross-section towards the aperture portion containing the end of the flexible wire forming said electrical contact.

2-4. (canceled)

5. An arrangement as claimed in claim 1, wherein said second die plate member comprises an integrated and unitarily formed interposer and guard plate structure of said testing arrangement.

6. An arrangement as claimed in claim 1 wherein the end of each said flexible wire, which is anchored in said first die plate member including an anchoring shank portion connected to the bottom wall of said aperture with which it is associated.

7. An arrangement as claimed in claim 1, wherein said die plate members include a multiplicity of said apertures in a grid-shaped array, each containing a respective electrical contact of a flexible wire for simultaneous probing of a multiplicity of electrical products.

8. A method of testing of electrical products at a wafer or semiconductor chip module level, said method comprising:
providing a first die plate member having a plurality of apertures formed therein;
providing a second die plate member arranged in a closely spaced surface relationship with said first die plate member having a plurality of through-extending apertures formed therein in substantial alignment with the apertures in said first die plate member;
having resilient spring elements interconnecting said first and second die plate members to facilitated said second die plate member being biased into surface contact with said first die plate member responsive to pressure exerted by a wafer or chip module which is being tested against an opposite surface of said second die plate member;
arranging a flexible wire which extends through, respectively, each of the apertures of said first and second die plate members, each said flexible wire having one end anchored in said first die plate member and an opposite end forming an electrical contact with said module during testing of the electrical products;
normally maintaining said second die plate member in a spaced relationship with said first die plate member during which the tip of each of said flexible wire forming the electrical contact is recessed with the therewith associated aperture in said second die plate member:
the tip of each said flexible wire forming the electrical contact projects from the aperture associated therewith into contact with the module upon said second die plate member being pressed by said module opposite the biasing force of resilient spring elements tending to separate said first and second die plate members; and
each aperture in said second die plate member having a V-shaped cross-section over a portion of the thickness of said die plate member, which widens towards the first die plate member, and at the apex of said V-shaped cross-section, said aperture comprising a transition zone into a wider cylindrical cross-section towards the aperture portion containing the end of the flexible wire forming said electrical contact.

9-11. (canceled)

12. A method as claimed in claim 8, wherein said die plate members include a multiplicity of said apertures in a grid-shaped array, each containing a respective electrical contact of a flexible wire for simultaneous probing of a multiplicity of electrical products.
